(19) United States
(12) Patent Application Publication
(10) Pub. No.: US 2025/0133846 A1
(43) Pub. Date: Apr. 24, 2025

(54) PIXEL STRUCTURE, CMOS IMAGING SENSOR, AND METHOD FOR MANUFACTURING THE PIXEL STRUCTURE

(71) Applicant: TAIWAN SEMICONDUCTOR MANUFACTURING COMPANY LTD., HSINCHU (TW)

(72) Inventors: KUO-CHENG LEE, TAINAN CITY (TW); CHUN-LIN FANG, TAINAN CITY (TW); BO-GE HUANG, TAINAN CITY (TW)

(21) Appl. No.: 18/490,780

(22) Filed: Oct. 20, 2023

(51) Int. Cl. H01L 27/146

(52) U.S. Cl. CPC H10F 39/80373; H10F 39/014; H10F 39/18

(57) ABSTRACT

A pixel structure is provided. The pixel structure includes a substrate, a photo detecting region, a first transfer gate, and a second transfer gate. The photo detecting region is in the substrate and has a first doping type. The first transfer gate includes a first portion in contact with a first side of the substrate and a second portion connected with the first portion and embedded in the substrate. An end of the second portion of the first transfer gate is adjacent to a side of the photo detecting region. The second transfer gate is adjacent to the first transfer gate. An end of the second transfer gate in the substrate is projectively over the photo detecting region. A method for manufacturing a pixel structure is also provided.

### BACKGROUND

Digital cameras and optical imaging devices employ image sensors. Image sensors convert optical images to digital data that may be represented as digital images. An image sensor includes a pixel array (or grid) for detecting light and recording intensity (brightness) of the detected light. The pixel array responds to the light by accumulating a charge. The accumulated charge is then used (for example, by other circuitry) to provide a color and brightness signal for use in a suitable application, such as a digital camera.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates top views of a pixel array according to a comparative embodiment of the present disclosure.

FIG. 2A illustrates a top view of a pixel array according to some embodiments of the present disclosure.

FIG. 2B illustrates a cross-sectional view of a pixel array along a line AA′ in FIG. 2A according to some embodiments of the present disclosure.

FIG. 3 illustrates a top view of a pixel array according to some embodiments of the present disclosure.

FIG. 4 illustrates a top view of a pixel array according to some embodiments of the present disclosure.

FIG. 5 illustrates a top view of a pixel array according to some embodiments of the present disclosure.

FIG. 6 illustrates a cross-sectional view of a CMOS image sensor according to some embodiments of the present disclosure.

FIG. 7 illustrates a schematic circuit diagram of a CMOS image sensor according to some embodiments of the present disclosure.

FIGS. 8A to 8F illustrate cross-sectional views of manufacturing a pixel structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

Integrated circuit (IC) technologies undergo continuous enhancements, with a focus on scaling down device geometries to achieve lower fabrication costs, increased device integration density, faster speeds, and improved performance. Complementary metal-oxide-semiconductor (CMOS) image sensors is a critical component in digital imaging devices, capturing light and converting it into electronic signals for further processing. Generally, CMOS image sensors (CIS) have emerged as the primary technology for image sensors in both commercial and scientific applications. That is, CMOS image sensors are highly regarded for their low power consumption, rapid readout capabilities, and adaptability to various signal processing techniques and thus be utilized in a wide range of applications, including digital cameras, smartphones, security cameras, and scientific imaging devices.

The structure of CMOS image sensor consists of various elements, with the transfer gate (or called gate electrode of the transfer transistor) being one of the central components. The core of a CMOS image sensor is a pixel array, comprising numerous individual photodiodes. These photodiodes serve as light-sensitive elements and are responsible for converting incoming photons into electron-hole pairs when exposed to light. At the heart of this pixel array lies the transfer gate, which plays a pivotal role in the sensor's operation. The transfer transistor having the transfer gate is a specialized transistor that acts as a switch, controlling the movement of charge carriers, specifically electrons, from the photodiodes to the subsequent stages of the sensor.

Adjacent to the transfer gate, some peripheral circuits such as the reset transistor, also known as the reset gate, may be employed to ensure that the photodiode starts each imaging cycle with a known state by clearing any residual charge. This step is important for accurate image capture.

There are some source follower transistors can be included in the CMOS image sensor. The source follower transistor often referred to as S-FET, which serves to buffer and amplify the signal generated by the photodiode. This amplification may enhance the sensitivity of the sensor. Furthermore, the CMOS image sensor may include column amplifiers, which are typically situated at the periphery of the pixel array. These amplifiers further boost the signal from each pixel, improving overall performance. In addition, the row and column select lines in the CMOS image sensor are essential for pixel readout and data transfer. They enable the selection of specific pixels for readout and coordinate the orderly transfer of data from the pixel array to downstream processing stages.

By utilizing the components above, the CMOS image sensor can work as the phases start with the reset, where the reset transistor clears the photodiode to a known state. During the exposure phase, the photodiodes accumulate charge in response to incoming light. Then, in the transfer phase, the transfer gate is activated, allowing the accumulated charge to flow to the source-follower transistor for amplification. Finally, during the readout phase, the amplified signals are read out sequentially or in parallel through the column amplifiers and subsequently converted into a digital image.

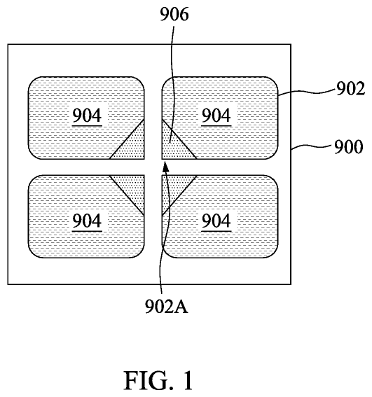

Referring to FIG. 1, in some comparative embodiments, a CMOS image sensor includes a pixel array 900 having a plurality of pixels 902 arranged in an array. As the top view of the pixel array 900 illustrated in the figure, each of the pixels 902 in the pixel array 900 includes a photo detecting region 904, while a transfer transistor having a planar transfer gate 906 is located in proximity to a corner 902A of the pixel 902. The planar transfer gate 906 is configured to establish an electric field that moves electrons in the photodiodes to a floating diffusion region.

In some comparative embodiments, the planar transfer gates 906 in the pixel array 900 are close to a center portion of the pixel array 900, and each of the planar transfer gate 906 is substantially or entirely over the photo detecting region 904 in the pixel 902. In some embodiments, there are some periphery circuits coupled with the pixel 902, such as a source follower (SF) and a capacitor switch (CS). In some embodiments, the capacitor switch can include a MIM capacitor formed in a back-end-of-line structure and electrically connected to the pixel through conductive contacts and metal layers.

Since the planar transfer gate 906 is only located on the surface of the substrate having the photo detecting region 904, the electrons in the photodiodes may not be effectively read out and blooming could be caused accordingly. Blooming refers to a phenomenon in which excess electrical current in a particular pixel overflows or spreads to a neighboring pixel when that pixel is operating at full capacity. This occurrence of unwanted current spreading and affecting nearby cells is commonly referred to as blooming noise.

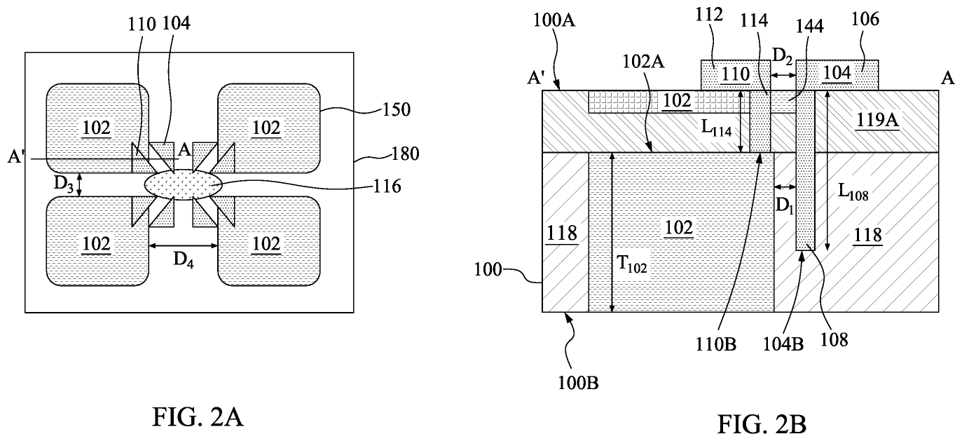

Referring to FIG. 2A and FIG. 2B, in some embodiments of the present disclosure, a pixel structure 150 in a pixel array 180 of a CMOS image sensor includes more than one transfer gates. Each of the pixel structures 150 is an image sensing pixel. As the cross-sectional view of the pixel structure 150 illustrated in FIG. 2B, the pixel structure 150 includes a substrate 100 having a first side 100A and a second side 100B opposite to the first side 100A.

In some embodiments, the substrate 100 includes a semiconductor material such as silicon or germanium. In some embodiments, the substrate 100 may include other semiconductor materials, such as silicon germanium, silicon carbide, gallium arsenide, gallium phosphide, indium phosphide, indium arsenide, indium antimonide, or combinations thereof. The substrate 100 may be doped with an N-type dopant, such as arsenic or phosphor, and may be doped with a P-type dopant, such as boron or the like. In some embodiments, the CMOS image sensor is configured to receive radiation incident from the second side 100B of the substrate 100 and employed as a back-side illuminated (BSI) image sensor. In some embodiments, active components, such as transistors, or passive components, such as doped regions, conductive features, or dielectric layers, are formed on the first side 100A of the substrate 100.

In some embodiments, the pixel structure 150 includes a photo detecting region 102 with a first doping type in the substrate 100 and in proximity to the second side 100B of the substrate 100. In some embodiments, the substrate 100 may have a second doping type, and the photo detecting region 102 may at least comprise a doped sensing layer with a first doping type opposite to the second doping type. The first doping type is one of the n-type and p-type, and the second doping type is the other one of the n-type and p-type.

In some embodiments, each of the pixel structures 150 in the pixel array 180 further includes a first transfer gate 104 disposed at the first side 100A of the substrate 100 and a second transfer gate 110 disposed at the first side 100A of the substrate 100 and adjacent to the first transfer gate 104. In some embodiments, both the first transfer gate 104 and the second transfer gate 110 may have a portion embedded in the substrate 100. As shown in FIG. 2B, in some embodiments, the first transfer gate 104 includes a first portion 106 in contact with the first side 100A of the substrate 100 and a second portion 108 connected with the first portion 106 and embedded in the substrate 100. In some embodiments, the second transfer gate 110 includes a third portion 112 in contact with the first side 100A of the substrate 100 and a fourth portion 114 connected with the third portion 112 and embedded in the substrate 100. In some embodiments, the third portion 112 of the second transfer gate 110 is leveled with the first portion 106 of the first transfer gate 104. In some embodiments, as shown in FIG. 2A, the shape of the first portion 106 of the first transfer gate 104 is substantially identical to that of the third portion 112 of the second transfer gate 110.

The two-transfer gate design in some embodiments of the present disclosure is for increasing the full well capacity (FWC) of the photo detecting region 102.

The full well capacity is one of the primary parameters of CMOS image sensors. The full well capacity refers to the maximum amount of charge, typically measured in electrons, that each individual pixel in the sensor's photodiode can accumulate before saturating. In simpler terms, it signifies the pixel's capacity to collect and store photons (light) during the exposure phase. Generally, there are several factors that may influence the level of the full well capacity of a CMOS image sensor, such as photodiode size, voltage biasing, integration time, temperature, pixel design, a manufacturing process, and pixel scaling.

To be specific, the physical dimensions of the pixel or the photodiode within each pixel may directly affect its full well capacity, for example, larger photodiodes can store more charge, leading to a higher full well capacity. The voltage applied to the photodiode during operation may cause influence as well, for instance, higher bias voltages can increase the full well capacity by allowing the photodiode to accumulate more charges before reaching its saturation point. A longer duration of the exposure phase, referred to as an integration time, may provide more opportunities for photons to strike the photodiode, resulting in increased charge accumulation and a higher full well capacity. In an aspect of temperature, the temperature may influence the full well capacity because it affects the intrinsic properties of the semiconductor material in the photodiode, and therefore lower temperatures can sometimes lead to higher full well capacity values due to reduced thermal noise. Furthermore, the design and architecture of the CMOS image sensor, including factors like the presence of micro lenses or anti-blooming structures, can influence the full well capacity as well. The micro lenses can enhance light collection, potentially increasing the full well capacity, while anti-blooming structures may limit charge spill-over but could reduce the full well capacity. In addition, the variations in the manufacturing process can also affect the full well capacity of CMOS image sensors, such as the differences in doping levels, materials, and fabrication techniques can lead to variations in the full well capacity among sensors.

In some embodiments of the present disclosure, an additional transfer gate structure is added to the pixel structure to avoid the leakage caused by an overflow path layer. The overflow path layer may be referred to as the buried channel overflow path, and being a portion within the buried channel. The buried channel is a region within an ordinary CMOS image sensor, typically situated beneath the photodiode array. The function of the buried channel is to provide a controlled pathway or channel for charge carriers, such as electrons, to travel through. The buried channel can be created by doping the semiconductor material used in the sensor's construction. The purpose of the buried channel is to facilitate efficient charge transport. For instance, when the photons strike the photodiode, the photodiode may generate electron-hole pairs. The electrons produced in this process need a clear path to move toward the collection junction or amplifier without recombining with holes. Briefly, the buried channel may help prevent such recombination, ensuring that the generated charge is effectively collected, thereby enhancing the sensor's sensitivity and signal integrity.

On the other hand, the overflow path layer is to serve as an auxiliary storage area for excess charge carriers, specifically electrons. During instances of intense light exposure or when the photodiode generates an abundance of charge that exceeds the standard pixel capacity, excess electrons can be directed to the overflow path, effectively preventing pixel saturation. This feature is important for preserving image quality when capturing scenes with a wide range of light intensities. That is, theoretically, by offering a supplementary storage area, the overflow path may expand the full well capacity of the CMOS image sensor, enabling it to handle a broader dynamic range of light without compromising image fidelity.

However, since the overflow path may also cause the extra leakage of electrons and thus limit the maximum full well capacity of the CMOS image sensor, some embodiments of the present disclosure employ deeper vertical transfer gate to replace the buried channel.

As the exemplary embodiment shown in FIGS. 2A and 2B, the first transfer gate 104 is used to replace the buried channel, while a length of the first transfer gate 104 in the substrate 100 (i.e., the length L₁₀₈ of the second portion 108 of the first transfer gate 104) is greater than a length of the second transfer gate 110 in the substrate 100 (i.e., the length L₁₁₄ of the fourth portion 114 of the second transfer gate 110). That is, the first transfer gate 104 and the second transfer gate 110 are structurally different, for example, at least an end 104B of the first transfer gate 104 is located much deeper in the substrate 100 than an end 110B of the second transfer gate 110.

In some embodiments, the end 104B of the first transfer gate 104 is adjacent to a side of the photo detecting region 102 in the substrate 100. In some embodiments, the distance D₂ between the end 104B of the first transfer gate 104 and the side of the photo detecting region 102 is no greater than the distance D₁ between the first transfer gate 104 and the second transfer gate 110. In some embodiments, the end 110B of the first transfer gate 110 in the substrate 100 is projectively over the photo detecting region 102. In other words, not only the lengths of the first transfer gate 104 and the second transfer gate 110 are different, but the first transfer gate 104 and the second transfer gate 110 are particularly located in different positions relative to the photo detecting region 102. In some embodiments, the length L₁₀₈ of the second portion 108 of the first transfer gate 104 is no less than about 50% of the thickness T₁₀₂ of the photo detecting region 102, whereas the length L₁₁₄ of the fourth portion 114 of the second transfer gate 110 is in a range of about 10% to about 20% of the thickness T₁₀₂ of the photo detecting region 102. Accordingly, since the first transfer gate 104 is much longer than the second transfer gate 110 in the substrate 100, the arrangement of the first transfer gate 104 and the second transfer gate 110 relative to the photo detecting region 102 also has corresponding considerations.

In some embodiments, the photo detecting region 102 is projectively below the second transfer gate 110. In some embodiments, the end 110B of the second transfer gate 110 is in contact with a top 102A of the photo detecting region 102. In some embodiments, the first transfer gate 104 is substantially adjacent to the photo detecting region 102. In some embodiments, the first transfer gate 104 is free from projectively over the photo detecting region 102. In other words, in some embodiments, a side (i.e., an interface between the photo detecting region 102 and the material of the substrate 100) of the photo detecting region 102 is projectively below a space between the first transfer gate 104 and the second transfer gate 110.

By using the group of the first transfer gate 104 and the second transfer gate 110 (i.e., a dual vertical transfer gate design), such structure, or called anti-blooming structure, can eliminate the over-saturation in the CMOS image sensor. To be more detailed, the depth or length of the first transfer gate 104 in the substrate 100 (e.g., the length L₁₀₈) should be equal to or greater than about 50% of the thickness T₁₀₂ of the photo detecting region 102 to achieve a lower threshold voltage. The length of the first transfer gate 104 in the substrate 100 is crucial in the function that transferred the electrons from the deeper portion of the photo detecting region 102 to the floating diffusion region. In contrast, the second transfer gate 110 is employed to reduce the transfer potential, thus improving image lag. The depth or length of the second transfer gate 110 in the substrate 100 (e.g., the length L₁₁₄) typically falls within a range of about 10% to about 20% of the thickness T₁₀₂ of the photo detecting region 102. The length of the second transfer gate 110 in the substrate 100 is related to the location of the photo detecting region 102. Furthermore, such length of the second transfer gate 110 is much effectively benefited for the function that the second transfer gate 110 may stabilize the electric field in the shallower portion of the substrate 100 (e.g., near the first side 100A of the substrate 100). In some embodiments, the length L₁₁₄ is no greater than half of the L₁₀₈. Furthermore, in some embodiments, the deeper of the two transfer gates, namely the first transfer gate 104, is utilized for transferring excess charges and storing it in a capacitor. This function helps mitigate issues such as image distortion and blooming. On the other hand, in some embodiments, the shallower of the two transfer gates, namely the second transfer gate 110, is employed to transfer charge from the photo detecting region 102 while simultaneously reading signals from it. Particularly, the second transfer gate 110 can serve to reduce the potential voltage in the channel. That is, as the thickness of the photo detecting region 102 increases, the potential voltage would have also increased to guide the electrons to the channel. But, by using the pair of transfer gates in the present disclosure, the electric field generated in the pixel is more stable, which can maintain a better conductivity and prevent such increase in potential voltage.

Regarding the structure feature of each of the transfer gates, in some embodiments, the first transfer gate 104 includes a gate oxide or gate dielectric. In some embodiments, the thickness of the gate dielectric in the first transfer gate 104 is about 32 Å for a maximum voltage of 3.3V. In some embodiments, the first transfer gate 104 includes a horizontal polysilicon gate structure (i.e., the first portion 106 of the first transfer gate 104) and a vertical polysilicon gate structure (i.e., the second portion 108 of the first transfer gate 104). In some embodiments, the horizontal polysilicon gate structure is in contact with the surface (e.g., the surface at the first side 100A) of the substrate 100 and connected with an operation voltage. In some embodiments, the vertical polysilicon gate structure is used to control the channel and transfer charging.

Similar with the first transfer gate 104, in some embodiments, the second transfer gate 110 also includes the gate dielectric. The gate dielectric may include silicon oxide, silicon nitride, silicon oxynitride, other suitable materials, or combinations thereof. In other embodiments, the gate dielectric may include high-k materials such as metal oxides, metal nitrides, metal silicates, transition metal-oxides, transition metal-nitrides, transition metal-silicates, oxynitride of metals, metal aluminates, zirconium silicate, zirconium aluminate, hafnium oxide, or combinations thereof. In some embodiments, the thickness of the gate dielectric in the second transfer gate 110 is also about 32 Å for a maximum voltage of 3.3V. In some embodiments, the second transfer gate 110 also includes a horizontal polysilicon gate structure (i.e., the third portion 112 of the second transfer gate 110) and a vertical polysilicon gate structure (i.e., the fourth portion 114 of the second transfer gate 110). In some embodiments, the distance D₂ between the first transfer gate 104 and the second transfer gate 110 is no less than about 0.13 μm. In case of the distance D₂ is too short, the first transfer gate 104 would be too close to the second transfer gate 110 and the photo detecting region 102, and such design may not accomplish the function of transferring electronic. In some embodiments, the material of the first transfer gate 104 and the second transfer gate 110 can include a metallic material (e.g., tungsten, copper, silver) instead of polysilicon.

Referring to FIG. 2A, in some embodiments, the pixel array 180 further includes a floating diffusion region 116 is disposed adjacent to the pixel structures 150. In some embodiments, the floating diffusion region 116 is surrounded by four pixel structures 150. The floating diffusion region 116 acts as a charge tank in which charges can be read out in a readout operation. In some embodiment, the floating diffusion region 116 has an N-type dopant. In some embodiments, the floating diffusion region 116 has a doping concentration greater than a doping concentration of the photo detecting region 102.

Referring to FIG. 2B, in some embodiments, the pixel structure 150 further includes a deep doped layer 118 having a second doping type in the substrate 100. In some embodiments, the deep doped layer 118 has a doping concentration smaller than that of the photo detecting region 102. In some embodiments, the pixel structure 150 further includes a first doped layer 119A having the second doping type in the substrate 100 and in proximity to the first side 100A of the substrate 100. In some embodiments, the pixel structure 150 further includes a second doped layer 119B having P+ doping and laterally surrounded by the first doped layer 119A.

Additionally, in some embodiments, a heavily doped region 144 can be located between the first transfer gate 104 and the second transfer gate 110. This heavily doped region functions as a channel between the first transfer gate 104 and the second transfer gate 110 and contains a high level of N+ doping. Its purpose is to provide a pathway for reading out the charges from the detecting region 102 through a conductive contact landed on the heavily doped region 144.

In the exemplary embodiment shown in FIG. 2A, each of the first transfer gates 104 and the second transfer gates 110 have a triangular shape from a top view perspective. In some embodiments, a cross-sectional shape of each of the first transfer gates 104 or each of the second transfer gates 110 over the surface of the substrate 100 is a rectangle.

In addition, in some embodiments, as the pixel array 180 shown in FIG. 2A, the distance between adjacent pixel structures can be different, particularly, the distances between the photo detecting regions 102 in the pixel array 180 can be different. For example, the distance D₃ between the left or right two photo detecting regions 102 is shorter than the distance D₄ between the upper or lower two photo detecting regions 102 in the pixel array 180 from a top view perspective shown in FIG. 2A. In some embodiments, the distance between the two adjacent photo detecting regions 102 without having the first transfer gate 104 (e.g., the distance D₃) is shorter than the distance between the two adjacent photo detecting regions 102 with one or more first transfer gate 104 located therein (e.g., the distance D₄). In other words, since the CMOS image sensor in the present disclosure employs the first transfer gate 104 as a deeper vertical transfer gate to replace the buried channel, the existing of the first transfer gate 104 might affect the distance between the photo detecting regions 102 of adjacent pixel structures 150.

In some embodiments, the transfer gates in each pair of the first transfer gate 104 and the second transfer gate 110 (i.e., the first transfer gate 104 and the second transfer gate 110 in a single pixel structure 150) are arranged symmetrically along a diagonal of the pixel structure 150.

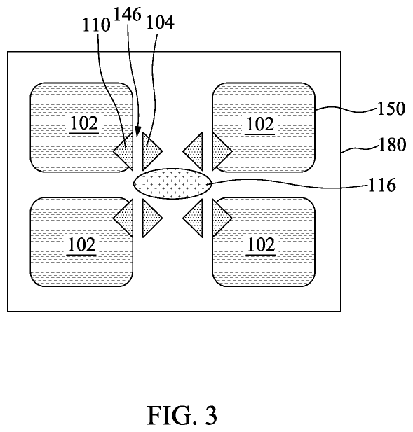

In other embodiments, as shown in FIG. 3, both the first transfer gates 104 and the second transfer gates 110 retain a triangular shape from a top view perspective. However, the arrangement in FIG. 3 differs from that illustrated in the previous embodiment in FIG. 2A. In the embodiment shown in FIG. 3, within a single pixel structure 150, a side of the first transfer gate 104 is vertically in line with a side of the photo detecting region 102, whereas the second transfer gate 110 is distanced from the side of the photo detecting region 102 by a gap 146 from the top view perspective. In some embodiments, the gap 146 between the first transfer gate 104 and the second transfer gate 110 is parallel to one side of the photo detecting region 102. In some embodiments, the shapes of the first transfer gate 104 and the second transfer gate 110 are symmetrical along the gap 146.

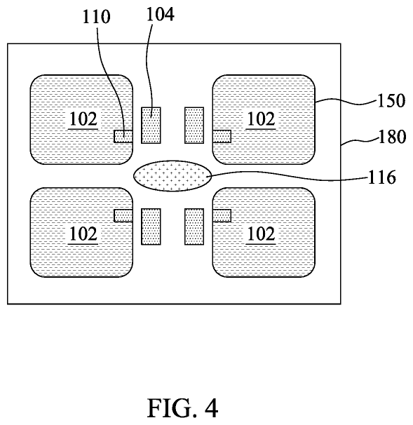

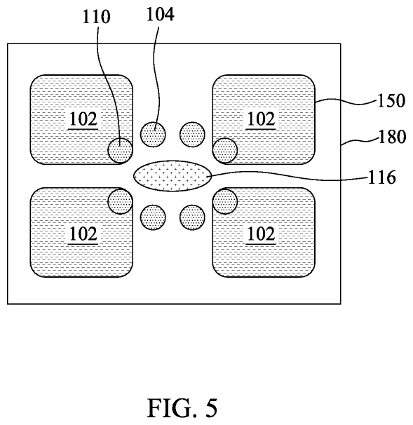

Furthermore, as shown in FIG. 4, in some embodiments, either the first transfer gate 104 or the second transfer gate 110 may have a rectangular shape from a top view perspective. Additionally, the profile of the first transfer gate 104 may differ from that of the second transfer gate 110. For instance, the area of the first transfer gate 104, particularly the area of the first portion 106, can be greater than that of the second transfer gate 110, particularly, the area of the third portion 114. That is, the profiles of the first transfer gate 104 and the second transfer gate 110 from a top view perspective are primarily defined by their respective portions situated on the substrate 100 surface. Even when the shapes and profiles of the first transfer gate 104 and the second transfer gate 110 differ when viewed from the top, the shapes and profiles of the portions embedded in the substrate, such as the second portion of the first transfer gate 104 and the fourth portion of the second transfer gate 110, may still remain the same in some embodiments. Additionally, as seen in FIG. 5, in some embodiments, both the first transfer gate 104 and the second transfer gate 110 may adopt a circular shape.

In some embodiments, a cross-sectional area of the first transfer gate 104 is no less than about 0.04 μm². In some embodiments, a cross-sectional area of the second transfer gate 110 is no less than about 0.04 μm². In some embodiments, for a more specific considerations, a cross-sectional area of the first transfer gate 104 is no less than about 0.042 μm². The cross-sectional areas of the first transfer gate 104 and the second transfer gate 110 are crucial to the ability of guiding the electrons from the deeper portion of the photo detecting region 102 and stabilizing the electric field in the shallower portion of the photo detecting region 102, respectively. In some embodiments, a cross-sectional area of the second transfer gate 110 is no less than about 0.042 μm². These minimum of the cross-sectional areas of the first transfer gate 104 and the second transfer gate 110 are the areas of the first portion 106 of the first transfer gate 104 and the third portion 112 of the second transfer gate 110 from the top view perspective.

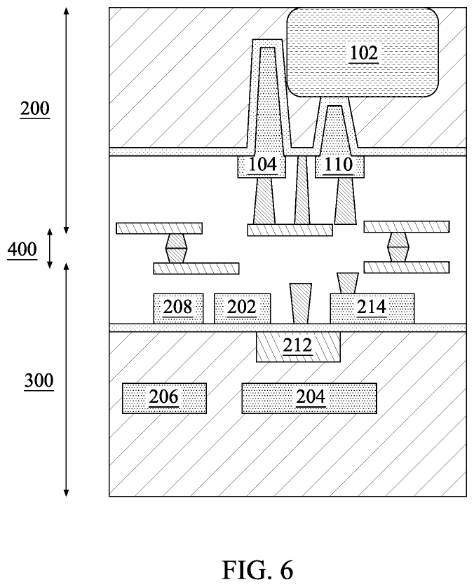

Referring to FIG. 6, in some embodiments, a plurality of conductive contacts and metal layers can be formed on the first side 100A of the substrate 100. These conductive contacts are positioned on the top surfaces (i.e., the surface near the first side 100A of the substrate 100) of both the first transfer gate 104 and the second transfer gate 110 within a pixel region. In some embodiments, the pixels can be fabricated on a first wafer 200 (e.g., a pixel wafer), while certain peripheral circuits or components, such as the source follower 202, the analog-to-digital converter 204 (ADC), the capacitors 206, the capacitor switch 208, the switch (SW) 210, etc., can be fabricated on a second wafer 300 (e.g., an analog wafer). In some embodiments, the second wafer 300 includes a floating diffusion region 212 in proximity to the side bonded with the first wafer 200. These two wafers can be bonded together using semiconductor packaging techniques, and a bonding structure 400 may thus be sandwiched by the first wafer 200 having pixels and the second wafer 300 having analog circuits.

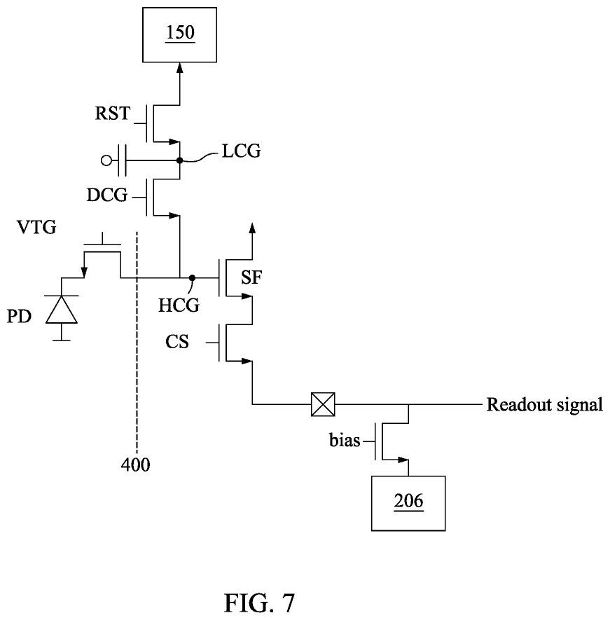

FIG. 7 is a schematic circuit diagram of the CMOS image sensor according to some embodiments of the present disclosure, particularly, the readout pathway of the signal from the photo diode region is illustrated in the diagram.

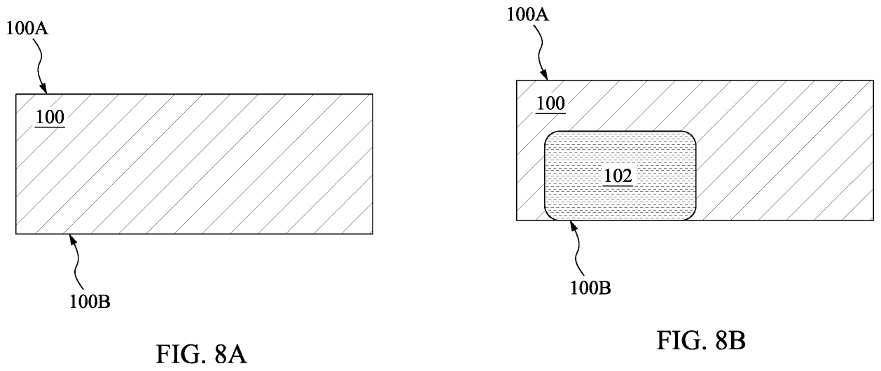

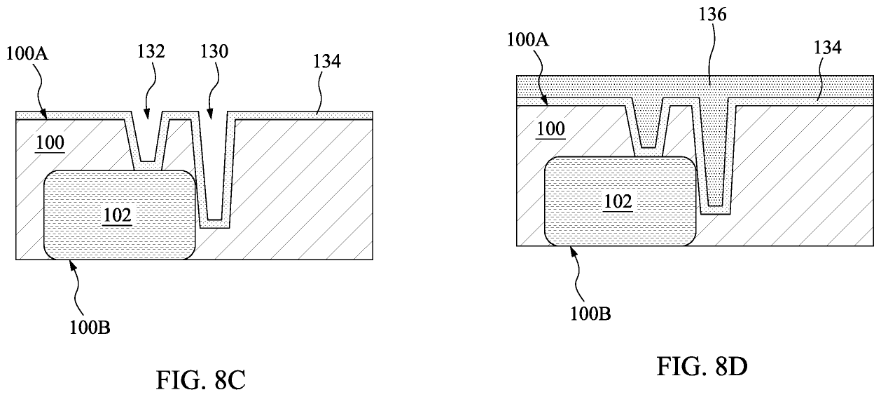

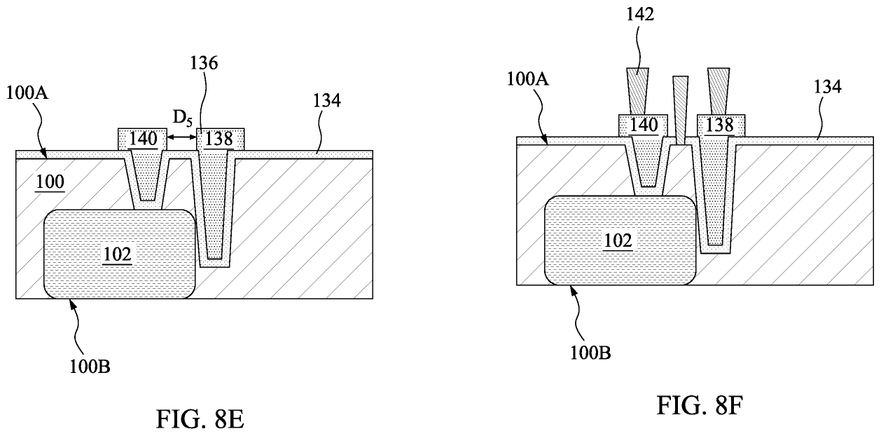

Referring to FIG. 8A, in some embodiments, in manufacturing a pixel structure 150, such as the example that previously illustrated in FIG. 2B, the substrate 100 having the first side 100A and the second side 100B opposite to the first side 100A can be received firstly. In some embodiments, the substrate 100 may include other semiconductor materials, such as silicon germanium, silicon carbide, gallium arsenide, gallium phosphide, indium phosphide, indium arsenide, indium antimonide, or combinations thereof. The substrate 100 may be doped with an N-type dopant, such as arsenic or phosphor, and may be doped with a P-type dopant, such as boron or the like.

Next, as shown in FIG. 8B, in some embodiments, a plurality of first dopants can be implanted in the substrate 100 to form the photo detecting region 102 in the substrate 100. The photo detecting region 102 is in proximity to the second side 100B of the substrate 100.

In some embodiments, a blanket implant, or alternatively, a grading epitaxial growth process may be performed to form the photo detecting region 102 with the first doping type. In some embodiments, another dopant species is then implanted into the substrate 100 to form the floating diffusion region 116. In some embodiments, the dopant species may include a second doping type (e.g., an n-type dopant such as phosphorous) that is implanted into the substrate 100. In other embodiments, the dopant species may include the first doping type. In some embodiments, a thinning down operation can be performed from the second side 100B of the substrate 100 to reduce the thickness of the substrate 100. The substrate 100 may be thinned by a chemical-mechanical polishing process and/or other etching processes.

Then, as shown in FIG. 8C, in some embodiments, a first recess 130 and a second recess 132 can be formed at the first side 100A of the substrate 100. The first recess 130 and the second recess 132 can be formed by selectively etching the substrate 100 in one or more etching operations. In some embodiments, the first recess 130 is free from over the photo detecting region 102, whereas the second recess 132 is directly over the photo detecting region 102.

Subsequently, in some embodiments, a gate dielectric layer 134 can be deposited over the first side 100A of the substrate 100. The gate dielectric layer 134 can conform to the profile of the first side 100A of the substrate 100, particularly, the profiles of the first recess 130 and the second recess 132 at the first side 100A of the substrate 100. In some embodiments, the gate dielectric layer 134 may include silicon oxide, silicon nitride, silicon oxynitride, other suitable materials, or combinations thereof. In other embodiments, the gate dielectric layer 134 may include high-k materials such as metal oxides, metal nitrides, metal silicates, transition metal-oxides, transition metal-nitrides, transition metal-silicates, oxynitride of metals, metal aluminates, zirconium silicate, zirconium aluminate, hafnium oxide, or combinations thereof. In some embodiments, the thickness of the gate dielectric layer 134 is about 32 Å.

Referring to FIG. 8D, in some embodiments, a polysilicon layer 136 can be deposited over the first side 100A of the substrate 100 to fill the first recess 130 and the second recess 132. The polysilicon layer 136 is utilized for forming the transfer gates. In some embodiments, the polysilicon layer 136 can be replaced by metallic material, such as tungsten, copper, silver, or the like.

Referring to FIG. 8E, in some embodiments, the polysilicon layer 136 is patterned to form a first polysilicon gate structure 138 at the first recess 130 and a second polysilicon gate structure 140 at the second recess 132. The first polysilicon gate structure 138 is departed from the second polysilicon gate structure 140 by a distance D₅. In some embodiments, the distance D₅ crosses a side of the photo detecting region 102. Since the recesses are filled by polysilicon, the first polysilicon gate structure 138 and the second polysilicon gate structure 140 includes horizontal portions leveled to each other and vertical portions extending into the substrate 100 from the first side 100A.

Referring to FIG. 8F, in some embodiments, a middle-end-of-line process can be performed to form the middle-end-of-line structure over the first side 100A of the substrate 100. In some embodiments, the middle-end-of-line process includes the operation forming a plurality of conductive contacts 142 landing on the first polysilicon gate structure 138 and the second polysilicon gate structure 140. In some embodiments, an additional etching operation can be performed to remove the gate dielectric layer 134 between the first polysilicon gate structure 138 and the second polysilicon gate structure 140 to expose the substrate 100, hence the conductive contacts 142 may subsequently landed thereon to in contact the heavily doped region 144/floating diffusion region 116 of the substrate 100. In some embodiments, a back-end-of-line process can be performed to from a metallization layer over the middle-end-of-line structure. Additionally, in some instances, a capacitor structure can be coupled to the first polysilicon gate structure 138 by either forming the metallization layer or bonding an analog wafer containing the capacitor structure onto the substrate 100.

Overall, the present disclosure enhances electron capture in the pixel structure of a CMOS image sensor by introducing an additional transfer gate to efficiently store the over-saturated charge in a capacitor, thereby improving the acquisition of signals generated by the photodiode. This approach allows for the avoidance of blooming issues without reducing the full well capacity of the CMOS image sensor. The additional transfer gate, when compared to the inherent one, has a longer length and extends deeper into the sides of the photo-detecting region. By combining pixels with two transfer gates of varying lengths, the CMOS image sensor proposed in the present disclosure indeed demonstrates benefits in terms of anti-blooming effectiveness and maintaining maximum full well capacity.

In one exemplary aspect, a pixel structure is provided. The pixel structure includes a substrate, a photo detecting region, a first transfer gate, and a second transfer gate. The substrate has a first side and a second side opposite to the first side. The photo detecting region has a first doping type. The photo detecting region is in the substrate and in proximity to the second side of the substrate. The first transfer gate is disposed at the first side of the substrate. The first transfer gate includes a first portion in contact with the first side of the substrate; and a second portion connected with the first portion and embedded in the substrate, wherein an end of the second portion of the first transfer gate is adjacent to a side of the photo detecting region. The second transfer gate is disposed at the first side of the substrate and adjacent to the first transfer gate. An end of the second transfer gate in the substrate is projectively over the photo detecting region.

In another exemplary aspect, a CMOS imaging sensor is provided. The CMOS imaging sensor includes a substrate, a pixel array. The substrate has a first side and a second side opposite to the first side. The pixel array includes a plurality of pixels, each of the pixels includes a first transfer gate at the first side of the substrate, a second transfer gate at the first side of the substrate and adjacent to the first transfer gate, and a photo detecting region with a first doping type in the substrate. The photo detecting region is projectively below the second transfer gate. A side of the photo detecting region is laterally adjacent to an end of the first transfer gate.

In yet another exemplary aspect, a method for preparing PVD target structure is provided. The method includes the following operations. A substrate having a first side and a second side opposite to the first side is received. A plurality of first dopants are implanted in the substrate to form a photo detecting region in the substrate. A first recess and a second recess are formed at the first side of the substrate, wherein the first recess is directly over the photo detecting region and the second recess is free from over the photo detecting region. A polysilicon layer is deposited on the first side of the substrate to fill the first recess and the second recess. The polysilicon layer is patterned to form a first polysilicon gate structure at the first recess and a second polysilicon gate structure at the second recess, wherein the first polysilicon gate structure is departed from the second polysilicon gate structure by a distance.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel structure, comprising:
a substrate having a first side and a second side opposite to the first side;
a photo detecting region with a first doping type in the substrate and in proximity to the second side of the substrate;
a first transfer gate disposed at the first side of the substrate, the first transfer gate comprises:
a first portion in contact with the first side of the substrate; and
a second portion connected with the first portion and embedded in the substrate,
wherein an end of the second portion of the first transfer gate is adjacent to a side of the photo detecting region; and
a second transfer gate disposed at the first side of the substrate and adjacent to the first transfer gate, wherein an end of the second transfer gate in the substrate is projectively over the photo detecting region.

2. The pixel structure of claim 1, wherein a length of the second portion of the first transfer gate is no less than about 50% of a thickness of the photo detecting region.

3. The pixel structure of claim 1, wherein a cross-sectional area of the first transfer gate is no less than about 0.04 μm².

4. The pixel structure of claim 1, wherein the second transfer gate comprises:
a third portion leveled with the first portion of the first transfer gate; and
a fourth portion connected with the third portion and embedded in the substrate, wherein an end of the third portion of the second transfer gate is over a top side of the photo detecting region.

5. The pixel structure of claim 4, wherein a distance between the first transfer gate and the second transfer gate is no less than about 0.13 μm.

6. The pixel structure of claim 4, wherein a length of the fourth portion of the second transfer gate is in a range of about 10% to about 20% of a thickness of the photo detecting region.

7. The pixel structure of claim 4, wherein a shape of the first portion of the first transfer gate is identical to a shape of the third portion of the second transfer gate from a top view perspective.

8. The pixel structure of claim 1, further comprising:
a bonding structure over the first side of the substrate; and
an analog circuit over the bonding structure,
wherein the analog circuit comprises a capacitor structure coupled with the first transfer gate.

9. A CMOS imaging sensor, comprising:
a substrate having a first side and a second side opposite to the first side;
a pixel array comprising a plurality of pixels, each of the pixels comprising:
a first transfer gate at the first side of the substrate;
a second transfer gate at the first side of the substrate and adjacent to the first transfer gate; and
a photo detecting region with a first doping type in the substrate and projectively below the second transfer gate, wherein a side of the photo detecting region is laterally adjacent to an end of the first transfer gate.

10. The CMOS imaging sensor of claim 9, wherein the first transfer gate is free from projectively over the photo detecting region.

11. The CMOS imaging sensor of claim 9, wherein a cross-sectional shape of the first transfer gate is a triangle, a rectangle, or a circle.

12. The CMOS imaging sensor of claim 9, further comprising a floating diffusion region in the substrate and laterally surrounded by four pixels.

13. The CMOS imaging sensor of claim 9, wherein a length of the first transfer gate embedded in the substrate is different from a length of the second transfer gate embedded in the substrate.

14. The CMOS imaging sensor of claim 9, wherein a length of the second transfer gate embedded in the substrate is no greater than half of a length of the first transfer gate embedded in the substrate.

15. The CMOS imaging sensor of claim 9, wherein a side of the photo detecting region is projectively below a space between the first transfer gate and the second transfer gate.

16. The CMOS imaging sensor of claim 9, wherein a distance between two adjacent first transfer gates is greater than a distance between two adjacent second transfer gates in the pixel array.

17. A method for manufacturing a pixel structure, the method comprising:
receiving a substrate having a first side and a second side opposite to the first side;
implanting a plurality of first dopants in the substrate to form a photo detecting region in the substrate;
forming a first recess and a second recess at the first side of the substrate, wherein the first recess is directly over the photo detecting region and the second recess is free from over the photo detecting region;
depositing a polysilicon layer on the first side of the substrate to fill the first recess and the second recess; and
patterning the polysilicon layer to form a first polysilicon gate structure at the first recess and a second polysilicon gate structure at the second recess, wherein the first polysilicon gate structure is departed from the second polysilicon gate structure by a distance.

18. The method of claim 17, wherein the distance crosses a side of the photo detecting region.

19. The method of claim 17, further comprising:
depositing a gate dielectric layer on the first side of the substrate prior to depositing the polysilicon layer.

20. The method of claim 19, further comprising:
forming a plurality of conductive contacts landing on the first polysilicon gate structure, the second polysilicon gate structure, and the substrate between the first polysilicon gate structure and the second polysilicon gate structure; and
coupling the first polysilicon gate structure with a capacitor structure.
